(19) United States
(12) Patent Application Publication
(10) Pub. No.: US 2019/0158037 A1
(43) Pub. Date: May 23, 2019

(54) HIGH-FREQUENCY AMPLIFIER UNIT AND HIGH-FREQUENCY POWER AMPLIFICATION APPARATUS

(71) Applicant: Mitsubishi Electric Corporation, Chiyoda-ku, Tokyo (JP)

(72) Inventor: Hiroyuki NONOMURA, Chiyoda-ku (JP)

(73) Assignee: Mitsubishi Electric Corporation, Chiyoda-ku, Tokyo (JP)

(21) Appl. No.: 16/091,723

(22) PCT Filed: Apr. 27, 2017
(86) PCT No.: PCT/JP2017/016653

§ 371 Date: Oct. 5, 2018

(30) Foreign Application Priority Data
Apr. 28, 2016 (JP) 2016-090264

(51) Int. Cl. H03F 1/30; H03F 3/21; H01L 23/467; H01L 23/40; H01L 23/66; H03F 3/68; H01L 23/473

(52) U.S. Cl. CPC H03F 1/30; H03F 3/211; H01L 23/467; H01L 23/4006; H01L 23/66; H03F 2200/423; H01L 23/473; H01L 2023/4087; H03F 2203/21142; H01L 2223/6644; H01L 2223/6633; H03F 3/68

(57) ABSTRACT

A cooler including a first surface on which a first high-frequency amplifier is installed in intimate contact therewith and a second surface which is opposite to the first surface and on which a second high-frequency amplifier is installed in intimate contact therewith. The first high-frequency amplifier amplifies a high-frequency signal and outputs an amplified high-frequency signal from an output terminal thereof. The second high-frequency amplifier amplifies a high-frequency signal and outputs an amplified high-frequency signal from an output terminal thereof. The cooler includes, on a third surface thereof, a first cooler terminal through which refrigerant flows into the cooler and a second cooler terminal through which the refrigerant flows out of the cooler. The third surface intersects the first surface and the second surface

### TECHNICAL FIELD

The present invention relates to a high-frequency amplifier unit and a high-frequency power amplification apparatus each having the arrangement of high-frequency amplifiers including semiconductor devices.

### BACKGROUND ART

In recent years, semiconductor devices with high output power, such as GaN FET and LD-MOS, have become widespread as power amplification devices with high-frequency signals. Such semiconductor devices, which have long service life, are increasingly used in high-output power amplification apparatuses which typically include amplifiers formed of vacuum devices.

In configuring a high-output power amplification apparatus with high-frequency signals which includes a semiconductor device, a single semiconductor device has output power lower than that of the vacuum device, leading to a need for power combination. Also, the high-output power amplification apparatus requires means for dissipating heat from each semiconductor device, and for higher output of a semiconductor device, the structure for power division, power combination, and heat radiation needs to be achieved in small size at low cost.

In order to meet such a need, Japanese Patent Laying-Open No. 61-27092 (see PTD 1) describes a high-frequency heating apparatus including a conductor plate and a radiating fin which is attached to the conductor plate in intimate surface contact therewith. Mounted in the conductor plate are an amplification circuit substrate and a solid-state component that forms at least an amplification portion of a solid high-frequency generation portion that is a high-frequency heating source.

Japanese Patent Laying-Open No. 2001-135965 (see PTD 2) describes an electronic apparatus in which cooling pipes, which have conventionally been configured for each line of electronics module, are integrated together to form a cooling layer as a structural component, and refrigerant passages, each configured between lines of electronics modules, are shaped into a flat rectangle. This leads to a dramatically improved cooling capability.

Japanese Patent Laying-Open No. 06-61389 (see PTD 3) describes a heat-pipe-connected semiconductor device in which a plurality of semiconductor accommodating packages accommodating semiconductors therein are continuously connected by a loop heat pipe formed annularly and shaped into a narrow tube, the loop heat pipe is filled with a condensable operating fluid to cause the operating fluid to contact the semiconductor devices accommodated in the semiconductor packages, and the plurality of semiconductor accommodating packages are arranged asymmetrically to the loop heat pipe.

### CITATION LIST

### Patent Documents

PTD 1: Japanese Patent Laying-Open No. 61-27092
PTD 2: Japanese Patent Laying-Open No. 2001-135965
PTD 3: Japanese Patent Laying-Open No. 06-61389

### SUMMARY OF INVENTION

### Technical Problem

In the high-frequency heating apparatus described in PTD 1, the radiating fin which is attached to the conductor plate in intimate surface contact therewith, in which the solid element that forms the amplification portion and the amplification circuit substrate are mounted, is subjected to forced-air cooling by cooling fans. This configuration employs an air cooling method, leading to poor cooling efficiency.

In the electronic apparatus described in PTD 2, the cooling layer that cools the electronics modules have a structure with a cooling passage formed into a flat rectangle. This structure causes the electronic modules to be arranged in the cooling layer planarly (two-dimensionally), increasing the size of the electronic apparatus.

In the heat-pipe-connected semiconductor device described in PTD 3, the plurality of semiconductor accommodating packages are continuously connected by the loop heat pipe formed annularly and shaped into a narrow tube. This configuration increases the dimensions of the heat-pipe-connected semiconductor device including the loop heat pipe. Also, the loop heat pipe may be routed in a complicated manner when the dimensions of the heat-pipe-connected semiconductor device are to be reduced.

The present invention has been made to solve the above problems, and has an object to provide a high-frequency amplifier unit and a high-frequency power amplification apparatus which have small size and good cooling efficiency.

### Solution to Problem

A high-frequency amplifier unit and a high-frequency power amplification apparatus according to the present invention include a cooler having a first surface on which a first high-frequency amplifier is installed in intimate contact therewith and a second surface which is opposite to the first surface and on which a second high-frequency amplifier is installed in intimate contact therewith. The first high-frequency amplifier amplifies a high-frequency signal and outputs an amplified high-frequency signal from an output terminal thereof. The second high-frequency amplifier amplifies a high-frequency signal and outputs an amplified high-frequency signal from an output terminal thereof. The cooler includes, on a third surface thereof, a first cooler terminal through which refrigerant flows into the cooler and a second cooler terminal through which the refrigerant flows out of the cooler. The third surface intersects the first surface and the second surface.

### Advantageous Effects of Invention

The present invention includes two high-frequency amplifiers installed on the first surface of the cooler and the second surface of the cooler opposite to the first surface, thus achieving a small-sized high-frequency amplifier unit capable of efficiently cooling the high-frequency amplifier. The use of this high-frequency amplifier unit allows miniaturization of the high-frequency power amplification apparatus that combines output powers of the plurality of high-frequency amplifiers and outputs combined output power.

### BRIEF DESCRIPTION OF DRAWINGS

FIG. 1A is a perspective view of a high-frequency power amplification apparatus according to Embodiment 1 of the present invention.

FIG. 1B shows an external appearance of the high-frequency power amplification apparatus according to Embodiment 1 of the present invention.

FIG. 2 is a block diagram showing the high-frequency power amplification apparatus according to Embodiment 1 of the present invention.

FIG. 3 is a side view showing a configuration of the high-frequency amplifier unit according to Embodiment 1 of the present invention.

FIG. 4 is a top view of a cooler according to Embodiment 1 of the present invention.

FIG. 5A shows a configuration of a power divider according to Embodiment 1 of the present invention.

FIG. 5B shows a configuration of the power divider according to Embodiment 1 of the present invention.

FIG. 6 shows a configuration of a power combiner according to Embodiment 1 of the present invention.

FIG. 7 shows a configuration of a cooling portion in Embodiment 1 of the present invention.

FIG. 8A shows a high-frequency power amplification apparatus composed of four units of high-frequency power amplification apparatuses of FIG. 1.

FIG. 8B shows a high-frequency power amplification apparatus composed of four units of high-frequency power amplification apparatuses of FIG. 1.

FIG. 9 is a configuration diagram showing a high-frequency power amplification apparatus according to Embodiment 2 of the present invention.

### DESCRIPTION OF EMBODIMENTS

### Embodiment 1

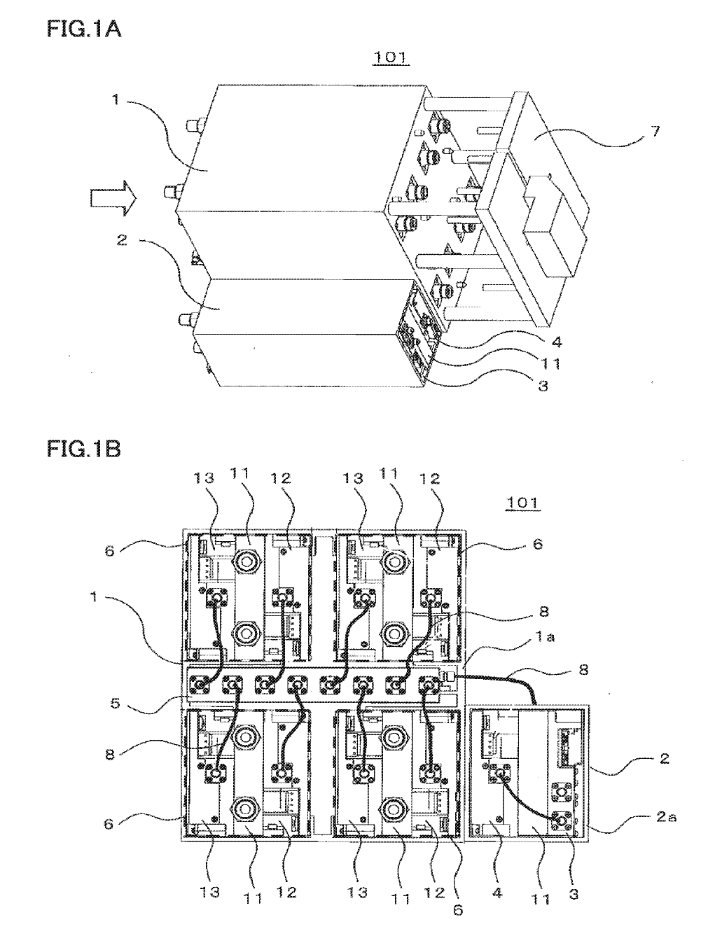

FIG. 1 shows a configuration of a high-frequency power amplification apparatus according to Embodiment 1 of the present invention. In FIG. 1, FIG. 1A is a perspective view of the high-frequency power amplification apparatus according to Embodiment 1, and FIG. 1B shows an external appearance of the high-frequency power amplification apparatus according to Embodiment 1 as seen from an arrow of FIG. 1A.

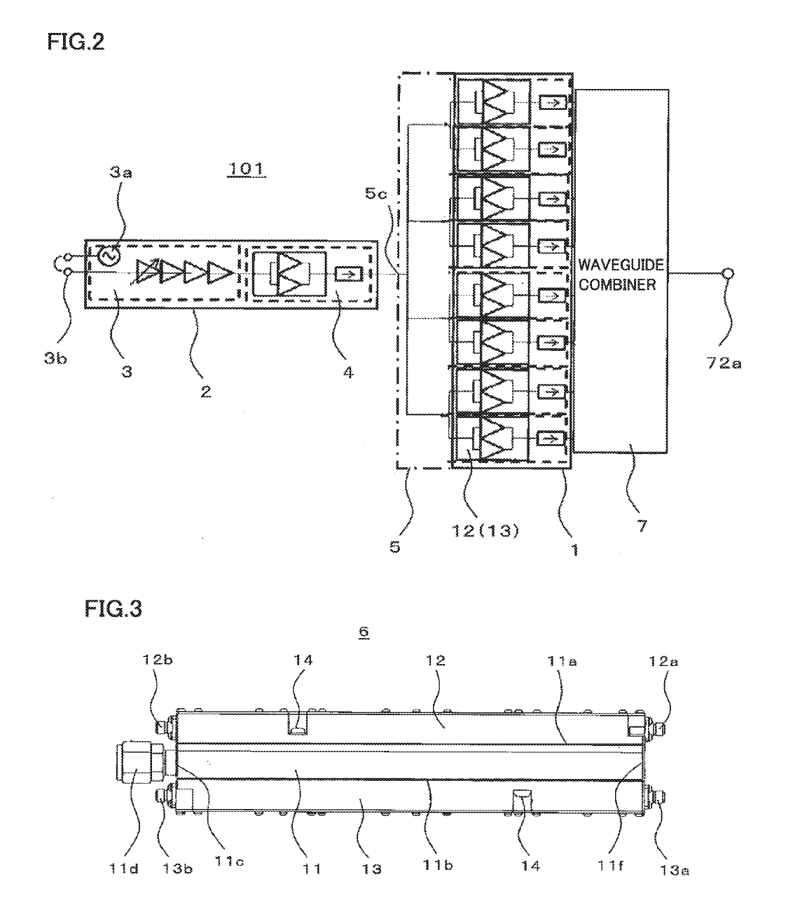

FIG. 2 is a block diagram showing the high-frequency power amplification apparatus according to Embodiment 1 of the present invention. A high-frequency power amplification apparatus 101 that amplifies a high-frequency signal includes a driver 2 that amplifies an input high-frequency signal to a high-frequency power level capable of driving a high-output power amplification portion 1. Driver 2 includes a preamplifier 3 formed of a semiconductor device and a high-output amplifier 4 formed of a semiconductor device that amplifies a high-frequency signal output from preamplifier 3.

High-frequency power amplification apparatus 101 includes a power divider 5 that divides the high-frequency signal output from high-output amplifier 4, high-output power amplification portion 1 formed of a plurality of high-frequency amplifier units 6 formed of semiconductors that receive input of the divided high-frequency signals and then amplify these signals to high-output power, and a power combiner 7 that combines the high-frequency signals amplified by the respective high-frequency amplifier units 6 of high-output power amplification portion 1.

Input terminals of preamplifier 3, high-output amplifier 4, power divider 5, and high-frequency amplifier unit 6 are connected to each other by a coaxial cable 8. An output terminal of high-frequency amplifier unit 6 and power combiner 7 are connected to each other by a coaxial connector, which is not shown in FIG. 1A. This coaxial connector may have a screw connection structure or a fitting structure. If it is difficult to directly connect high-frequency amplifier unit 6 and power combiner 7 to each other by a coaxial connector due to the limitations on assembly and mechanism, they may be connected to each other by a coaxial cable though a loss may increase.

Preamplifier 3 and high-output amplifier 4 are accommodated in a driver case 2a. High-frequency amplifier units 6 are accommodated in a high-output power amplification portion case 1a. Driver case 2a that accommodates power divider 5 and power combiner 7 is fixed to high-output power amplification portion case 1a.

The configuration of high-frequency amplifier unit 6 will be described with reference to the drawings. FIG. 3 is a side view showing the configuration of the high-frequency amplifier unit according to Embodiment 1 of the present invention. High-frequency amplifier unit 6 includes a cooler 11, a first high-frequency amplifier 12 installed on a first surface 11a of cooler 11 in intimate contact therewith, and a second high-frequency amplifier 13 installed on a second surface 11b opposite to first surface 11a in intimate contact therewith. First high-frequency amplifier 12 and second high-frequency amplifier 13 are fixed to cooler 11 with screws 14. First high-frequency amplifier 12 and second high-frequency amplifier 13 may be the same high-frequency amplifiers or different high-frequency amplifiers. In Embodiment 1, first high-frequency amplifier 12 and second high-frequency amplifier 13 are preferably the same high-frequency amplifiers. High-frequency amplifier unit 6 has a sandwich structure in which two high-frequency amplifiers, namely, first high-frequency amplifier 12 and second high-frequency amplifier 13 sandwich cooler 11.

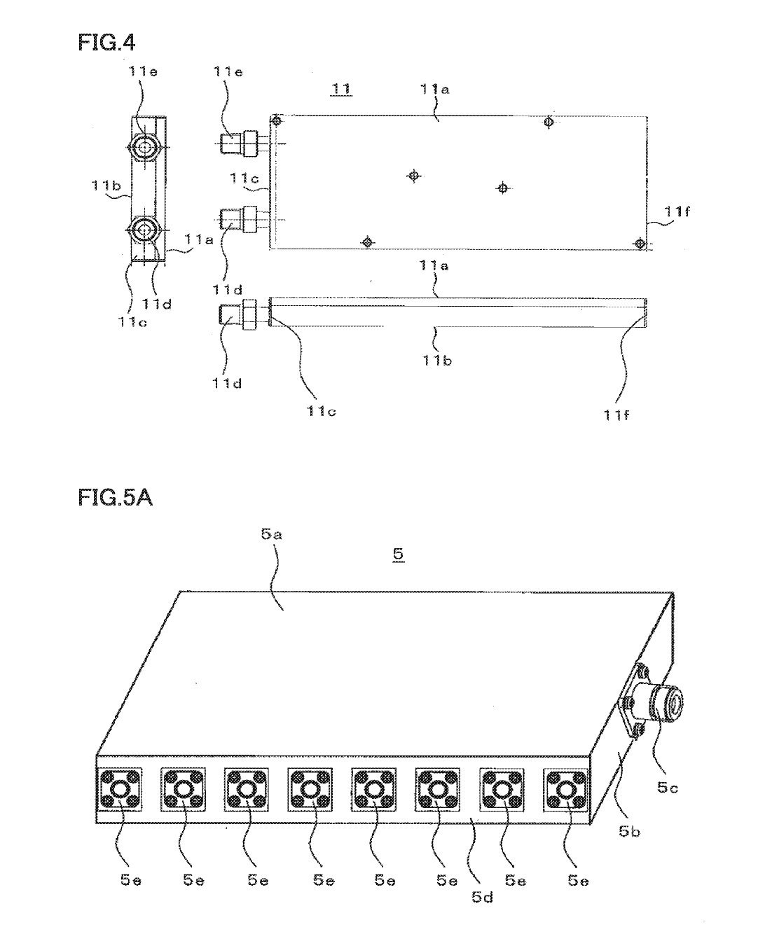

FIG. 4 is a top view of the cooler according to Embodiment 1 of the present invention. Cooler 11 is a cooler of refrigerant system which has a structure through which refrigerant passes. Used as the refrigerant is, for example, a liquid typified by water or a refrigerant gas typified by alternative CFC. Cooler 11 is made of metal and has a passage capable of optimum cooling by refrigerant.

With reference to FIGS. 3 and 4, cooler 11 includes a first cooler terminal 11d through which the refrigerant flows into cooler 11 and a second cooler terminal 11e through which the refrigerant flows out of cooler 11, on a third surface 11c orthogonal to both of first surface 11a and second surface 11b. Although FIGS. 3 and 4 show the case in which third surface 11c is orthogonal to both of first surface 11a and second surface 11b, depending on the layout of cooler 11, third surface 11c does not necessarily need to be orthogonal to these surfaces and intersect these surfaces at an appropriate angle.

In FIG. 3, an output terminal 12a of first high-frequency amplifier 12 is provided on the same side as a fourth surface 11f of cooler 11 opposite to third surface 11c in first high-frequency amplifier 12. Fourth surface 11f is orthogonal to both of first surface 11a and second surface 11b. That is to say, cooler 11 is formed into a rectangular parallelepiped. An output terminal 13a of second high-frequency amplifier 13 is provided on the same side as fourth surface 11f of cooler 11 in second high-frequency amplifier 13. Although FIGS. 3 and 4 show the case in which fourth surface 11f is orthogonal to both of first surface 11a and second surface 11b, depending on the layout of cooler 11, fourth surface 11f does not necessarily need to be orthogonal to these surfaces and may intersect these surfaces at an appropriate angle.

In FIG. 3, an input terminal 12b of first high-frequency amplifier 12 is provided on the same side as third surface 11c of cooler 11 in first high-frequency amplifier 12. An output terminal 13b of second high-frequency amplifier 13 is provided on the same side as third surface 11c of cooler 11 in second high-frequency amplifier 13.

Since first high-frequency amplifier 12 or second high-frequency amplifier 13 needs to be attached to the opposite surfaces of cooler 11, as shown in FIG. 3, first high-frequency amplifier 12 or second high-frequency amplifier 13 has an outside shape allowing screw fixing from first high-frequency amplifier 12 side or second high-frequency amplifier 13 side, not fixing with a lead-in screw from the cooler 11 side.

An interface for attaching first high-frequency amplifier 12 and second high-frequency amplifier 13 to cooler 11 is arranged to prevent overlap of the screw positions on the front and rear surfaces of cooler 11 and also prevent the division of a passage inside cooler 11, and is provided with a point symmetry structure. This structure allows high-frequency amplifiers to be arranged in any direction or in any combination. Passage interfaces (first cooler terminal 11d and second cooler terminal 11e) of cooler 11 are configured such that both the input and output thereof are collected on one side of cooler 11 (that is, collected on third surface 11c) and that the side opposite to the surface with the flow-path interface (that is, fourth surface 11f) is the power combiner 7 side. This configuration allows high-frequency amplifier unit 6 and power combiner 7 to be connected to each other by a coaxial connector with a shortest path to minimize the distance between high-frequency amplifier unit 6 and power combiner 7 and minimize a loss at the connection part between high-frequency amplifier unit 6 and power combiner 7.

High-frequency amplifier unit 6 has a sandwich structure in which first high-frequency amplifier 12 and second high-frequency amplifier 13 sandwich cooler 11. Preamplifier 3 is installed in place of first high-frequency amplifier 12 and high-output amplifier 4 is installed in place of second high-frequency amplifier 13 in cooler 11, allowing cooling of preamplifier 3 and high-output amplifier 4, that is, cooling of driver 2. This leads to standardization of the cooler for first high-frequency amplifier 12 and second high-frequency amplifier 13 and the cooler for preamplifier 3 and high-output amplifier 4.

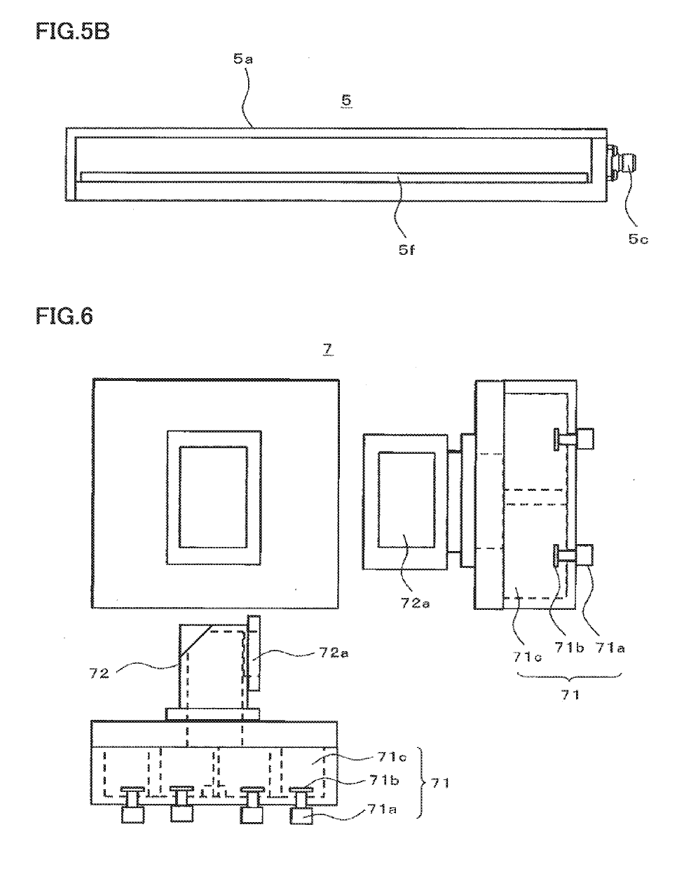

FIG. 5 shows the configuration of the power divider according to Embodiment 1 of the present invention. In FIG. 5, power divider 5 includes a case 5a, an input terminal 5c for high-frequency signals which is provided on a first lateral surface 5b of case 5a, and a plurality of output terminals 5e provided on a second lateral surface 5d orthogonal to first lateral surface 5b and output the divided high-frequency signals. There are output terminals 5e twice the number of high-frequency amplifier units 6. Input terminal 5c and output terminal 5e use a coaxial connector. Although FIG. 5 shows the case in which second lateral surface 5d is orthogonal to first lateral surface 5b, depending on the layout of power divider 5, second lateral surface 5d does not necessarily need to be orthogonal to first lateral surface 5b. Alternatively, second lateral surface 5d may intersect first lateral surface 5b at any angle. Output terminals 5e that output divided high-frequency signals may be provided on the lateral surface opposite to first lateral surface 5b on which input terminal 5c is provided.

A power division circuit is provided in case 5a. The power division circuit is formed on the surface of a dielectric substrate 5f made of ceramic or resin (e.g., glass epoxy) and is formed of a microstrip line. This power division circuit is connected with input terminal 5c and output terminals 5e.

FIG. 6 shows the configuration of the power combiner according to Embodiment 1 of the present invention. In FIG. 6, power combiner 7 is formed of a metal housing and includes a plurality of coaxial waveguide conversion portions 71 each formed of a coaxial connector 71a that receives an input of a high-frequency signal and a probe 71b inserted into a waveguide 71c formed inside the housing inside which a core line of coaxial connector 71a is formed. Power combiner 7 further includes a waveguide combination portion 72 that combines the high-frequency signals input to waveguides 71c and outputs the combined high-frequency signal from an output terminal 72a.

For example, at a frequency of about 2.45 GHz, an opening size of a standard waveguide is as very large as 109.22 mm×54.61 mm in EIAJ standard, WRI-22. Embodiment 1 provides a configuration in which the inputs of high-frequency amplifier unit 6 and power combiner 7 are connected by a coaxial connector, and subsequently, power combination is performed in the waveguide, leading to miniaturization.

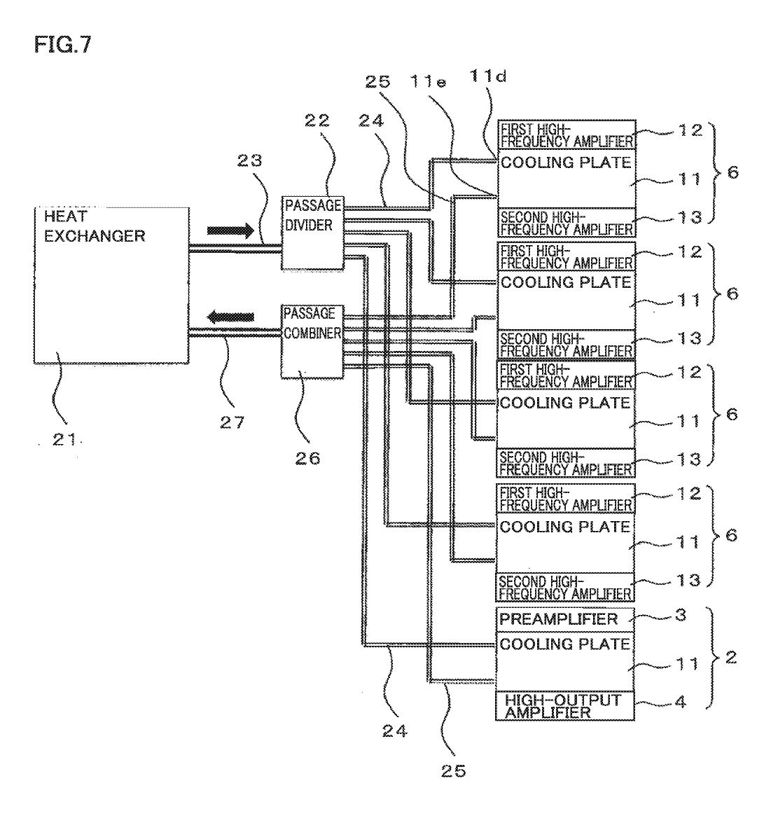

FIG. 7 shows the configuration of the cooling portion in Embodiment 1 of the present invention. The cooling portion includes a heat exchanger 21, a passage divider 22, and a feed main pipe 23 connecting heat exchanger 21 and passage divider 22 to each other. Passage divider 22 is connected to each of cooler 11 of high-frequency amplifier unit 6 and cooler 11 of driver 2 by a feed division pipe 24.

Cooler 11 of high-frequency amplifier unit 6 and cooler 11 of driver 2 are each connected to passage combiner 26 by a return division pipe 25. Passage combiner 26 and heat exchanger 21 are connected to each other by a return main pipe 27.

In FIG. 1, high-frequency power amplification apparatus 101 is formed of one driver 2 and four high-frequency amplifier units 6. On the adjacent surfaces of the adjacent high-frequency amplifier units 6, first high-frequency amplifier 12 of one high-frequency amplifier unit 6 and second high-frequency amplifier 13 of the other high-frequency amplifier unit 6 are disposed facing each other. In an alternative layout, on the adjacent surfaces of the adjacent high-frequency amplifier units 6, first high-frequency amplifier 12 of one high-frequency amplifier unit 6 and first high-frequency amplifier 12 of the other high-frequency amplifier unit 6 may be disposed facing each other, or the facing high-frequency amplifiers may be second high-frequency amplifiers 13.

An electrical operation of high-frequency power amplification apparatus 101 according to Embodiment 1 will be described with reference to FIGS. 1 to 7. In FIGS. 1 to 7, high-frequency power amplification apparatus 101 includes one driver 2 and four high-frequency amplifier units 6. A high-frequency signal input to input terminal 3b of preamplifier 3 is amplified to a first high-frequency power level, and the amplified high-frequency signal is output. The high-frequency signal of the first high-frequency power level output from the output terminal of preamplifier 3 is input to the input terminal of high-output amplifier 4, and is subsequently amplified to a second high-frequency power level that is a high-frequency power level before division such that the high-frequency power when power is divided by power divider 5 installed downstream of high-output amplifier 4 reaches a third high-frequency power level capable of driving high-frequency amplifier unit 6.

The high-frequency signal amplified to the second high-frequency power level output from the output terminal of high-output amplifier 4 is input to input terminal 5c of power divider 5, and is divided into values twice the number of high-frequency amplifier units 6, and the divide signals are subsequently output from division terminals 5e. In Embodiment 1, 8-way division is performed. This is because high-frequency amplifier unit 6 includes two high-frequency amplifiers, namely, first high-frequency amplifier 12 and second high-frequency amplifier 13. At this time, the high-frequency power level output from division terminal 5e is a third high-frequency power level. The high-frequency signals of the third high-frequency power level output from the division terminals of power dividers 5 are input to the respective input terminals (12b, 13b) of first high-frequency amplifiers 12 and second high-frequency amplifiers 13 of the respective high-frequency amplifier units 6. Hereinafter, first high-frequency amplifier 12 and second high-frequency amplifier 13 are described as the same high-frequency amplifiers.

The high-frequency signals of the third high-frequency power level input to the respective input terminals (12b, 13b) of first high-frequency amplifier 12 and second high-frequency amplifier 13 are amplified to a fourth high-frequency power level, and are subsequently output from the respective output terminals (12a, 13a) of first high-frequency amplifier 12 and second high-frequency amplifier 13. The high-frequency signals of the fourth high-frequency power level output from the output terminals (12a, 13a) of first high-frequency amplifier 12 and second high-frequency amplifier 13 of each high-frequency amplifier unit 6 are input to corresponding input terminals 71a of power combiner 7 (in FIG. 7, coaxial connector 71a). The number of input terminals 71a of power combiner 7 is twice the number of high-frequency amplifier units 6. In Embodiment 1, there are eight input terminals 71a. The high-frequency signals of the fourth high-frequency power level input to the respective input terminals 71a of power combiner 7 are combined to increase high-frequency power by the number of input terminals of power combiner 7 of the fourth high-frequency power level, and the combined high-frequency signal is output from output terminal 72a of power combiner 7.

High-frequency power amplification apparatus 101 can also operate as an oscillator by mounting oscillator 3a in preamplifier 3, inputting an output signal of oscillator 3a to input terminal 3b of preamplifier 3, and regarding the input signal as an input signal of the high-frequency signal of preamplifier 3. The configuration of preamplifier 3, high-output amplifier 4, and high-frequency amplifier units 6 which is composed based on predetermined output power is provided as a semiconductor amplifier, so that the configuration of a high-frequency power amplification apparatus with different output powers can be achieved relatively easily.

For example, FIG. 1 shows the configuration of 8-way combination of preamplifier 3, high-output amplifier 4, and high-frequency amplifiers (first high-frequency amplifiers 12, second high-frequency amplifiers 13) of high-frequency amplifier units 6. Alternatively, to obtain a configuration in which output power is reduced to ½, the configuration in which the number (m) of a plurality of (m) high-frequency amplifier units 6 is changed may be provided, such as 4-way combination of preamplifier 3, high-output amplifier 4, and high-frequency amplifiers (first high-frequency amplifiers 12, second high-frequency amplifiers 13) of high-frequency amplifier units 6.

High-frequency amplifier unit 6 has a configuration divided in units of high-frequency amplifiers (first high-frequency amplifier 12, second high-frequency amplifier 13). This configuration yields an effect that in the event of a breakdown of the high-frequency amplifiers (first high-frequency amplifier 12, second high-frequency amplifier 13) of any of m high-frequency amplifier units 6, high-frequency amplification apparatus 101 can continue operation though the output power thereof decreases, unlike in the event of a breakdown of a vacuum device such as a traveling-wave tube (TWT).

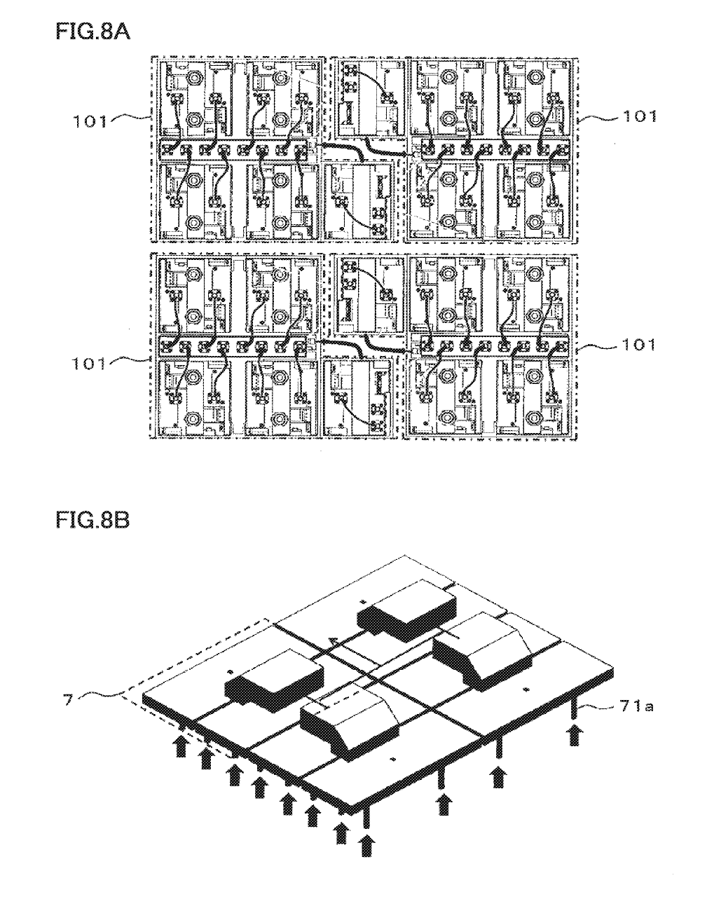

The structure in which preamplifier 3, high-output amplifier 4, and high-frequency amplifiers (first high-frequency amplifiers 12, second high-frequency amplifiers 13) are mounted to cooler 11 is arranged at a position shown in FIG. 1. This results in an arrangement in which when high-frequency power amplification apparatuses 101 are combined, where the whole of high-frequency power amplification apparatus 101 shown in FIG. 1 is regarded as a unit, to obtain 2ⁿ apparatuses as shown in FIG. 8 A, there occurs no interference and an optimum configuration is provided (FIG. 8 shows an example of n=2). The respective powers of high-frequency power amplification apparatus 101 shown in FIG. 1 are combined by 4-way combination indicated by a narrow-line arrow of FIG. 8 B, and the combined power is output in the end. The bold-line arrows of FIG. 8 B indicate powers input from the respective high-frequency amplifiers (first high-frequency amplifiers 12, second high-frequency amplifiers 13) to power combiners 7.

The exhaust heat passage and operation of high-frequency power amplification apparatus 101 according to Embodiment 1 will now be described with reference to FIG. 7. A refrigerant sent from heat exchanger 21 passes through feed main pipe 23 and flows into passage divider 22. Passage divider 22 divides the refrigerant to a plurality of feed division pipes 24. The number of divisions and the number of feed division pipes 24 are equal to a total count of high-frequency amplifier units 6 and driver 2. The refrigerants divided by passage divider 22 pass through feed division pipe 24 and flow into first cooler terminals 11d of coolers 11 of high-frequency amplifier units 6 and driver 2.

In cooler 11, the refrigerant that has absorbed the heats generated in first high-frequency amplifier 12, second high-frequency amplifier 13, preamplifier 3, and high-output amplifier 4 is emitted from second cooler terminals 11e of coolers 11 of high-frequency amplifier units 6 and driver 2, passes through return division pipe 25, and is returned to the return input of passage combiner 26. The number of return inputs and the number of return division pipes 25 are equal to a total count of high-frequency amplifier units 6 and driver 2. The refrigerants that have returned to the return input of passage combiner 26 meet at passage combiner 26, and the combined refrigerant passes through return main pipe 27 and returns to heat exchanger 21. Heat exchanger 21 exhausts the heat of the refrigerant to the outside so that the refrigerant is cooled, and the refrigerant is again sent form heat exchanger 21 to feed main pipe 23.

High-frequency amplifiers (first high-frequency amplifier 12, second high-frequency amplifier 13), preamplifier 3, and high-output amplifier 4 are installed to cooler 11 while sandwiching cooler 11 from the opposite sides of cooler 11, leading to a large area for heat exchange of cooler 11, which enables efficient cooling in reduced space.

### Embodiment 2

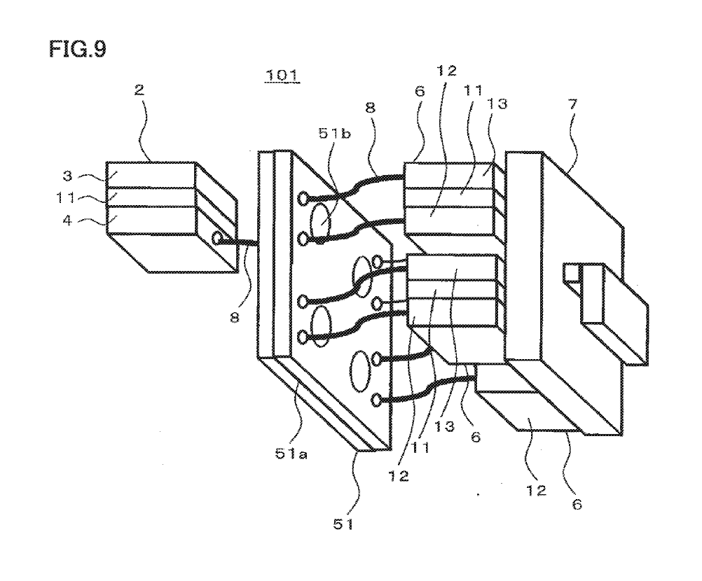

FIG. 9 shows a configuration of a high-frequency power amplification apparatus according to Embodiment 2 of the present invention. In FIG. 9, the components same as or similar to those of FIG. 1 are designated by the same reference numerals, and a description thereof will be omitted. With reference to FIG. 9, in Embodiment 2, power divider 51 is formed of a strip line formed in multilayer substrate 51a or on the surface of multilayer substrate 51a, in place of power divider 5 according to Embodiment 1. Multilayer substrate 51a includes ceramic or resin (e.g., glass epoxy) as a raw material. Also, in multilayer substrate 51a, through-holes 51b are formed at positions corresponding to first cooler terminals 11d and second cooler terminals 11e of cooler 11 of high-frequency amplifier unit 6. Although FIG. 9 does not show the configuration of the cooling portion, feed division pipe 24 and return division pipe 25 in FIG. 7 pass through through-holes 51b and are connected to passage divider 23 and passage combiner 26, respectively.

In FIG. 9, power divider 51 includes an input terminal that receives an input of a high-frequency signal from driver 2 on one surface, and on the other surface, includes an output terminal 51c that divides the high-frequency signal from driver 2 and outputs it to high-frequency amplifier unit 6 (first high-frequency amplifier 12, second high-frequency amplifier 13). That is to say, output terminal 51c is provided on the surface of power divider 51 which faces high-frequency amplifier unit 6.

In FIG. 9, power divider 51 and high-frequency amplifier unit 6 are connected to each other by coaxial cable 8. Directly connecting power divider 51 and high-frequency amplifier unit 6 to each other by a coaxial connector achieves a structure in which high-frequency amplifier units 6 are sandwiched between power divider 51 and power combiner 7, leading to miniaturization of high-frequency power amplification apparatus 101.

That is to say, the output terminal of driver 2 and the input terminal of power divider 51 are coupled to each other by fitting, and output terminal 51c of power divider 51 and input terminals of high-frequency amplifier unit 6 (first high-frequency amplifier 12, second high-frequency amplifier 13) are coupled by fitting. This integrates driver 2, power divider 51, and high-frequency amplifier unit 6 (first high-frequency amplifier 12, second high-frequency amplifier 13), leading to miniaturization of high-frequency power amplification apparatus 101.

The embodiments disclosed herein are illustrative and non-restrictive in every respect, and may be employed in an appropriate combination.

### REFERENCE SIGNS LIST

1 high-output power amplification portion, 1a high-output power amplification portion case, 2 driver, 2a driver case, 3 preamplifier, 3a oscillator, 3b input terminal, 4 high-output amplifier, 5 power divider, 5a case, 5b first lateral surface, 5c input terminal, 5d second lateral surface, 5e output terminal, 5f dielectric substrate, 6 high-frequency amplifier unit, 7 power combiner, 71 coaxial waveguide conversion portion, 71a coaxial connector (input terminal), 71b probe, 71c waveguide, 72 waveguide combination portion, 72a output terminal, 8 coaxial cable, 11 cooler, 11a first surface, 11b second surface, 11c third surface, 11d first cooler terminal, 11e second cooler terminal, 11f fourth surface, 12 first high-frequency amplifier, 12a output terminal, 12b input terminal, 13 second high-frequency amplifier, 13a output terminal, 13b input terminal, 21 heat exchanger, 22 passage divider, 23 feed main pipe, 24 feed division pipe, 25 return division pipe, 26 passage combiner, 27 return main pipe, 51 power divider, 51a multilayer substrate, 51b through-hole, 51c output terminal, 101 high-frequency power amplification apparatus.

1-11. (canceled)

12: A high-frequency amplifier unit comprising:
a cooler having a first surface on which a first high-frequency amplifier is installed in intimate contact therewith and a second surface which is opposite to the first surface and on which a second high-frequency amplifier is installed in intimate contact therewith, the first high-frequency amplifier configured to amplify a high-frequency signal inputted from a first high-frequency signal input terminal thereof and output an amplified high-frequency signal from a first high-frequency signal output terminal thereof, the second high-frequency amplifier configured to amplify a high-frequency signal inputted from a second high-frequency signal input terminal thereof and output an amplified high-frequency signal from a second high-frequency signal output terminal thereof,
the cooler including, on a third surface thereof, a first cooler terminal through which refrigerant flows into the cooler and a second cooler terminal through which the refrigerant flows out of the cooler, the third surface intersecting the first surface and the second surface,
the first high-frequency signal output terminal of the first high-frequency amplifier being provided on a same side as a fourth surface thereof opposite to the third surface in the first high-frequency amplifier,
the second high-frequency signal output terminal of the second high-frequency amplifier being provided on a same side as the fourth surface in the second high-frequency amplifier,
the first high-frequency signal input terminal being provided on a surface on a same side as the third surface in the first high-frequency amplifier,
the second high-frequency signal input terminal being provided on a surface on a same side as the third surface in the second high-frequency amplifier,
the first high-frequency signal input terminal and the second high-frequency signal input terminal being disposed respectively at a center portion of the first high-frequency amplifier and a center portion of the second high-frequency amplifier in a direction connecting the first cooler terminal and the second cooler terminal,
a first screw for fixing the cooler to the first high-frequency amplifier on a first surface side and a second screw for fixing the cooler to the second high-frequency amplifier on a second surface side not overlapping each other in position, and the first screw and the second screw being disposed at positions that are point-symmetric with respect to the cooler.

13: The high-frequency amplifier unit according to claim 12, wherein the fourth surface intersects the first surface and the second surface.

14: A high-frequency power amplification apparatus comprising:
a high-frequency amplifier unit according to claim 12; and
a power combiner configured to combine a first high-frequency signal output from the first high-frequency signal output terminal and a second high-frequency signal output from the second high-frequency signal output terminal and output a combined high-frequency signal.

15: A high-frequency power amplification apparatus comprising:
a plurality of high-frequency amplifier units according to claim 12; and
a power combiner configured to combine first high-frequency signals output from the first high-frequency signal output terminals of the plurality of high-frequency amplifier units and second high-frequency signals output from the second high-frequency signal output terminals of the plurality of high-frequency amplifier units and output a combined high-frequency signal.

16: The high-frequency power amplification apparatus according to claim 15, wherein a surface of the first high-frequency amplifier of one high-frequency amplifier unit of the plurality of high-frequency amplifier units which is opposite to a surface thereof being in intimate contact with the cooler and a surface of the first high-frequency amplifier of another high-frequency amplifier unit of the plurality of high-frequency ampligire units which is opposite to a surface thereof being in intimate contact with the cooler are disposed facing each other,
or a surface of the first high-frequency amplifier of the one high-frequency amplifier unit which is opposite to a surface thereof being in intimate contact with the cooler and a surface of the second amplifier unit of the other high-frequency amplifier unit which is opposite to a surface thereof being in intimate contact with the cooler are disposed facing each other.

17: The high-frequency power amplification apparatus according to claim 14, wherein the power combiner includes:
a coaxial waveguide conversion portion configured to receive an input of the first high-frequency signal output from the first high-frequency signal output terminal or the second high-frequency signal output from the second high-frequency signal output terminal and convert a coaxial line into a waveguide, and
a waveguide combination portion configured to combine the first high-frequency signals or the second high-frequency signals input to the coaxial waveguide conversion portion and output a combined high-frequency signal.

18: The high-frequency power amplification apparatus according to claim 17, wherein the first high-frequency signal output terminal or the second high-frequency signal output terminal is connected to the coaxial waveguide conversion portion by a first coaxial connector.

19: The high-frequency power amplification apparatus according to claim 17, wherein the first high-frequency signal output terminal or the second high-frequency signal output terminal is fitted with the coaxial waveguide conversion portion to be connected thereto.

20: The high-frequency power amplification apparatus according to claim 14, further comprising:
a power divider having a high-frequency signal output terminal for dividing the high-frequency signal and outputting divided high-frequency signals to the first high-frequency signal input terminal and the second high-frequency signal input terminal, the power divider including a dielectric substrate,
wherein the power divider includes through-holes provided at positions in the dielectric substrate which correspond to the first cooler terminal and the second cooler terminal.

21: The high-frequency power amplification apparatus according to claim 20, wherein the first high-frequency signal input terminal and the second high-frequency signal input terminal are fitted with the high-frequency signal output terminal of the power divider to be connected thereto by a second coaxial connector.

22: A high-frequency power amplification apparatus comprising
a plurality of high-frequency amplifier units according to claim 12;
a plurality of sub high-frequency amplifier units in each of which a surface of the first high-frequency amplifier of one high-frequency amplifier unit of the plurality of high-frequency amplifier units which is opposite to a surface thereof being in intimate contact with the cooler and a surface of the second high-frequency amplifier or the first high-frequency amplifier of another high-frequency amplifier unit of the plurality of high-frequency amplifier units which is opposite to a surface thereof being in intimate contact with the cooler are disposed facing each other; and
a power divider sandwiched between one sub high-frequency amplifier unit of a pair of sub high-frequency amplifier units among the plurality of sub high-frequency amplifier units and the other sub high-frequency amplifier unit of the pair of sub high-frequency amplifier units among the plurality of sub high-frequency amplifier units,
the power divider being sandwiched between the pair of sub high-frequency amplifier units while facing the first high-frequency amplifier and the second high-frequency amplifier of the one sub high-frequency amplifier unit and facing the first high-frequency amplifier and the second high-frequency amplifier of the other sub high-frequency amplifier unit in the pair of sub high-frequency amplifier unit.
the power divider having a high-frequency signal output terminal for dividing the high-frequency signal and outputting divided high-frequency signals to the first high-frequency signal input terminal and the second high-frequency signal input terminal of each of the one sub high-frequency amplifier unit and the other sub high-frequency amplifier unit of the pair of high-frequency amplifier units.

23: The high-frequency power amplification apparatus according to claim 22, further comprising:
a power combiner configured to combine a first high-frequency signal output from the first high-frequency signal output terminal of each of the pair of sub high-frequency amplifier units and a second high-frequency signal output from the second high-frequency signal output terminal of each of the pair of sub high-frequency amplifier units, and output a combined signal.

24: The high-frequency power amplification apparatus according to claim 23, wherein the power combiner includes:
a coaxial waveguide conversion portion configured to receive an input of the first high-frequency signal output from the first high-frequency signal output terminal or the second high-frequency signal output from the second high-frequency signal output terminal and convert a coaxial line into a waveguide, and
a waveguide combination portion configured to combine the first high-frequency signals or the second high-frequency signals input to the coaxial waveguide conversion portion and output a combined high-frequency signal.

25: The high-frequency power amplification apparatus according to claim 15, wherein the power combiner includes:
a coaxial waveguide conversion portion configured to receive an input of the first high-frequency signal output from the first high-frequency signal output terminal or the second high-frequency signal output from the second high-frequency signal output terminal and convert a coaxial line into a waveguide, and
a waveguide combination portion configured to combine the first high-frequency signals or the second high-frequency signals input to the coaxial waveguide conversion portion and output a combined high-frequency signal.

26: The high-frequency power amplification apparatus according to claim 16, wherein the power combiner includes:
a coaxial waveguide conversion portion configured to receive an input of the first high-frequency signal output from the first high-frequency signal output terminal or the second high-frequency signal output from the second high-frequency signal output terminal and convert a coaxial line into a waveguide, and
a waveguide combination portion configured to combine the first high-frequency signals or the second high-frequency signals input to the coaxial waveguide conversion portion and output a combined high-frequency signal.

27: The high-frequency power amplification apparatus according to claim 25, wherein the first high-frequency signal output terminal or the second high-frequency signal output terminal is connected to the coaxial waveguide conversion portion by a first coaxial connector.

28: The high-frequency power amplification apparatus according to claim 26, wherein the first high-frequency signal output terminal or the second high-frequency signal output terminal is connected to the coaxial waveguide conversion portion by a first coaxial connector.

29: The high-frequency power amplification apparatus according to claim 25, wherein the first high-frequency signal output terminal or the second high-frequency signal output terminal is fitted with the coaxial waveguide conversion portion to be connected thereto.

30: The high-frequency power amplification apparatus according to claim 26, wherein the first high-frequency signal output terminal or the second high-frequency signal output terminal is fitted with the coaxial waveguide conversion portion to be connected thereto.
